(19) United States
(12) Patent Application Publication
(10) Pub. No.: US 2025/0318086 A1
(43) Pub. Date: Oct. 9, 2025

(54) INTEGRATED LIQUID COOLING MANIFOLD FOR A DATA CENTER CABINET

(71) Applicant: Panduit Corp., Tinley Park, IL (US)

(72) Inventors: Eric Beaupre, Palos Park, IL (US); Surendra Chitti Babu, Naperville, IL (US)

(73) Assignee: Panduit Corp., Tinley Park, IL (US)

(21) Appl. No.: 19/093,833

(22) Filed: Mar. 28, 2025

Related U.S. Application Data
(60) Provisional application No. 63/631,532, filed on Apr. 9, 2024.
(60) Provisional application No. 63/680,745, filed on Aug. 8, 2024.

(51) Int. Cl. H05K 7/20; H05K 7/14

(52) U.S. Cl. CPC H05K 7/20781; H05K 7/1488

(57) ABSTRACT

A data center cabinet having a plurality of front to back members, a first manifold and a second manifold. The first manifold is secured to at least one of the plurality of front to back members on a first side of the cabinet. The second manifold is secured to at least one of the plurality of front to back members on a second side of the cabinet. The first manifold and the second manifold provide liquid to be distributed to and from equipment installed in the cabinet.

### CROSS REFERENCE TO RELATED APPLICATIONS

This application claims benefit to U.S. Provisional Patent Application No. 63/631,532, filed Apr. 9, 2024, and U.S. Provisional Patent Application No. 63/680,745, filed Aug. 8, 2024, the entirety of which is hereby incorporated by reference herein.

### FIELD OF THE INVENTION

The present invention relates to a liquid cooling manifold, and more particularly to an integrated liquid cooling manifold installed in a data center cabinet.

### BACKGROUND OF THE INVENTION

Datacenters have been predominantly cooled by air. With the increase in rack density and CPU/GPU chips getting more powerful, direct-to-chip (DtC) liquid cooling is starting to be adopted more than just in HPC and supercomputing. With air cooling, fans in IT equipment run on algorithms that increase or decrease their speed based on the power and temperature of IT equipment. DtC works by rejecting heat to liquid running through cold plates attached to the heat generating components such as CPU, GPU, memory, etc. Cool liquid flows into the cold plate capturing the heat and maintaining the hardware at its optimal temperature while warmer liquid returns to the pump and heat exchanger where it is cooled and sent back in a closed loop. Liquid used in DtC could be water, water & glycol, or dielectric fluid.

Server cabinet space is already at a premium with multiple rack PDUs (sometimes with redundant rack PDUs), power and datacom cables. In order to enable liquid cooling to enter the cabinet, manifolds have been attached to the rear side of the cabinet next to rack PDUs. Unfortunately, this configuration leads to insufficient space and adding water distribution systems (i.e., manifolds) to this space is challenging. Currently, one way to overcome the challenge is to use wider and deeper cabinets, but this configuration is still challenging. Another option is to use horizontal manifolds, but this leads to losing valuable RU space in the cabinet.

Therefore, a liquid cooling ready cabinet that reduces the space needed for liquid cooling would be desirable.

### SUMMARY OF THE INVENTION

A data center cabinet with a plurality of front to back members. A first manifold is secured to one of the front to back members on a first side of the cabinet. A second manifold is secured to one of the front to back members on a second side of the cabinet. The first manifold and the second manifold provide liquid to be distributed to and from equipment installed in the cabinet.

### BRIEF DESCRIPTION OF THE DRAWINGS

FIG. 1 is a perspective view of a cabinet with manifolds installed on each side of the cabinet.

FIG. 2 is a partial perspective view of the cabinet with the manifolds of FIG. 1 with the servers and hoses removed.

FIG. 3A is a left perspective view of the manifold of FIG. 1.

FIG. 3B is a right perspective view of the manifold of FIG. 1.

FIG. 4 is a partial perspective view of the cabinet with the manifolds of FIG. 2 with a server and hoses installed in the cabinet.

FIG. 5 is a perspective view of a double manifold.

FIG. 6 is a perspective view of a double manifold positioned at different angles.

FIG. 7 is a partial perspective view of the cabinet with manifolds installed on equipment rails with the server removed.

FIG. 8A is a front perspective view of the manifold installed on an equipment rail of FIG. 7.

FIG. 8B is a rear perspective view of the manifold installed on an equipment rail of FIG. 7.

FIG. 9A is a front perspective view of the manifold mounted to an equipment rails of FIG. 7.

FIG. 9B is a rear perspective view of the manifold mounted to an equipment rail of FIG. 9A.

FIG. 10A is a front perspective view of the manifold mounted to the equipment rail of FIG. 9A with a spring loaded clip installed on the equipment rail.

FIG. 10B is a rear perspective view of the manifold mounted to the equipment rail of FIG. 9B with a spring loaded clip installed on the equipment rail.

FIG. 11A is a rear perspective view of the manifold installed on the equipment rail of FIG. 10B with the spring loaded clip lifted from the manifold.

FIG. 11B is a rear perspective view of the manifold of FIG. 11A lifted with respect to the equipment rail.

FIG. 11C is a rear perspective view of the manifold of FIG. 11B disengaged from the equipment rail of FIG. 11B.

FIG. 12A is a left front perspective view of a manifold and a mounting plate installed on an equipment rail.

FIG. 12B is a right front perspective view of the manifold and a mounting plate installed on the equipment rail of FIG. 12A.

FIG. 13 is a partial perspective view of a cabinet with an in-rack PDU installed on an equipment rail.

FIG. 14 is an exploded view of the in-rack PDU and the equipment rail of FIG. 13.

FIG. 15A is a rear perspective view of the in-rack PDU partially installed on the equipment rail of FIG. 13.

FIG. 15B is a rear perspective view of the in-rack PDU installed on the equipment rail of FIG. 13.

### DETAILED DESCRIPTION

An innovative way to reduce the space required by liquid cooling manifolds is to integrate them directly into the cabinet. Integrating liquid cooling manifolds into the cabinet design leaves more space for other essentials such as power and data compared to a cabinet assembled with manifolds installed in the traditional way.

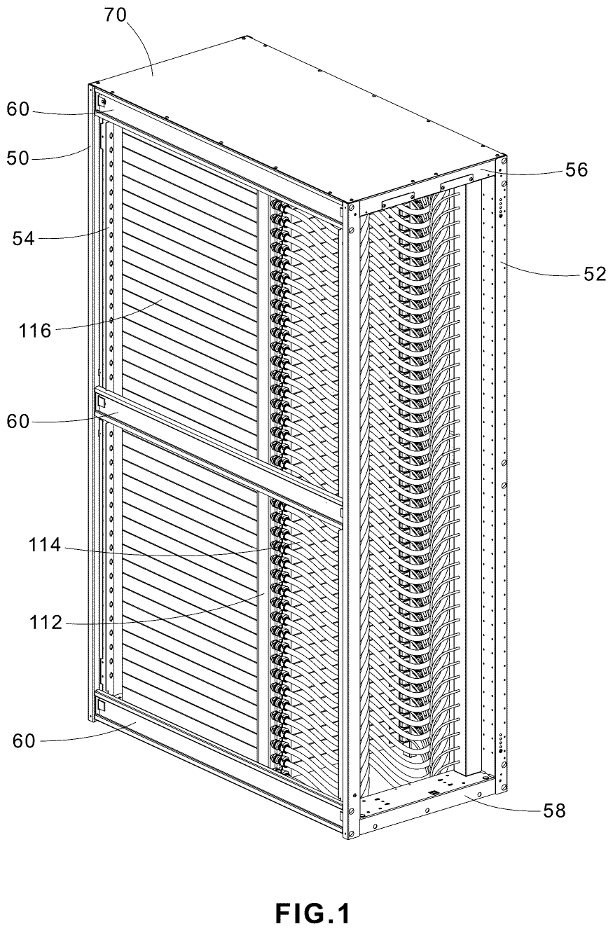

FIG. 1 illustrates a liquid cooling ready cabinet 50 with a cold manifold on the right side of the cabinet and a hot manifold on the left side of the cabinet. The cabinet 50 includes front vertical posts 52, back vertical posts 54, top side to side members 56, bottom side to side members 58, and front to back members 60. The cabinet 50 also includes a top panel 70, side panels and a door. The side panels and door are not illustrated so as to celarly see the inside of the cabinet 50. Each manifold 112 is assembled as part of the rack post or equipment rail as shown mounted in cabinet 50 with hoses 114 being routed to IT equipment 116, i.e. servers, as illustrated in FIG. 1.

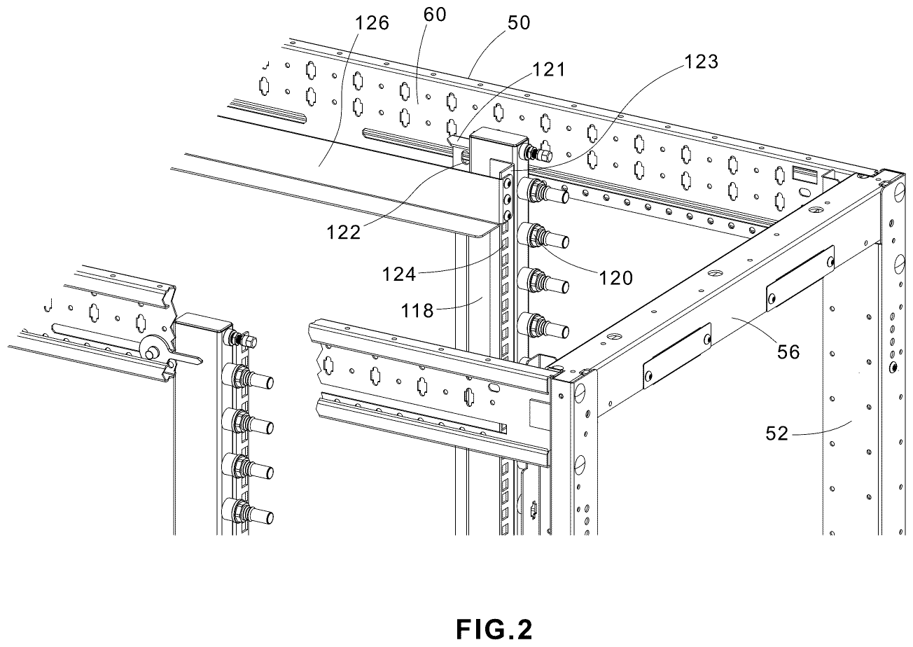

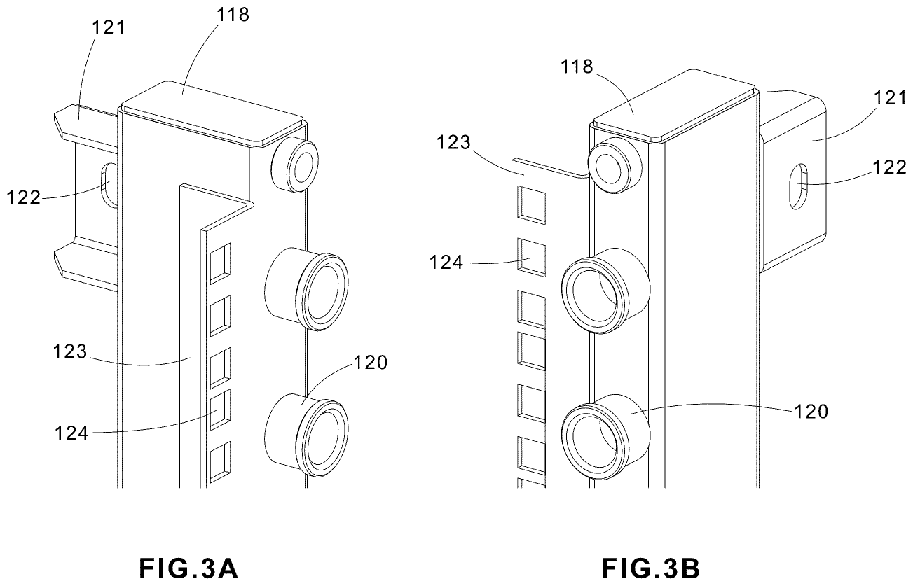

FIG. 2 illustrates integrated liquid cooling manifolds made from rectangular tubing 118 with liquid ports 120. The manifold 112 could be designed in other shapes such as square, cylindrial, etc., as desired. The manifold 112 mounts in a cabinet 50 by an integral bracket 121 that includes a mounting hole 122 (see FIGS. 3A-3B). The manifold 112 may be mounted to the front to back beam 60 of a cabinet 50 similar to an equipment rail as described in commonly owned U.S. Pat. No. 11,678,451, herein incorporated by reference. The manifold 112 may include as many brackets with mounting holes, as needed. The manifold 112 also includes a bracket 123 with a plurality of standard 19-inch rack mounting holes 124 which can be used to mount server rack rails 126 that support IT equipment, such as servers.

FIGS. 3A-3B illustrate the integrated rack support manifold 112 by itself. The manifold 112 includes a rectangular tubing 118 and at least one bracket 121 with mounting hole 122 to mount to the front to back members 60 in the cabinet 50. The manifold 112 provides ports 120 for liquid to be distributed to and from the servers. The manifold 112 also provides a bracket 123 with standard 19-inch rack mounting holes 124 extending the length of the manifold 112.

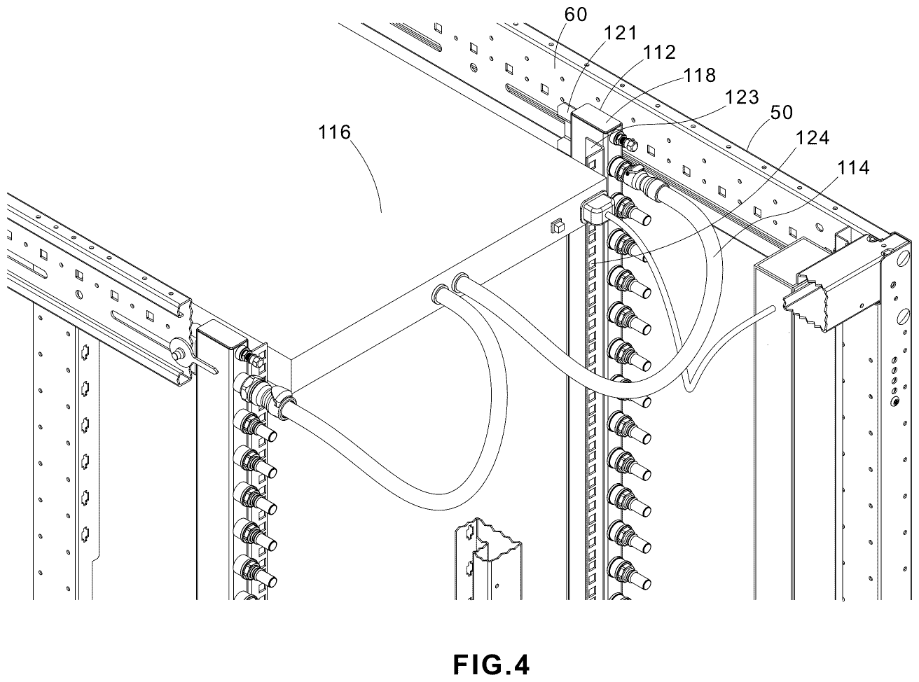

FIG. 4 shows the server 116 installed in the cabinet on the server rack rails. Hoses 114 connect the server to the manifolds 112 at fluid ports 120.

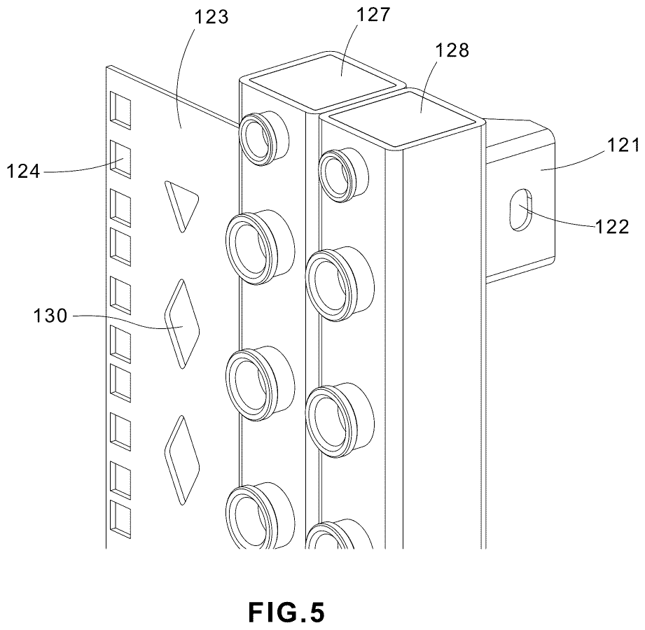

In addition to the single manifold installed on each side of the cabinet as shown in FIGS. 2, 3A, 3B, and 4, it is contemplated that both hot and cold manifolds 127, 128 can be provided on the same side of the cabinet in the same integrated rack support manifold as shown in FIG. 5. In rare cases where multiple hot and cold manifolds are required, a wider cabinet could be used with two manifolds on each side of the cabinet using an integrated rack support manifold similar to the one shown in FIG. 5.

In addition, if other features on the rack post or equipment rail are required, cable management mounting holes 130 may be included for mounting cable management accessories.

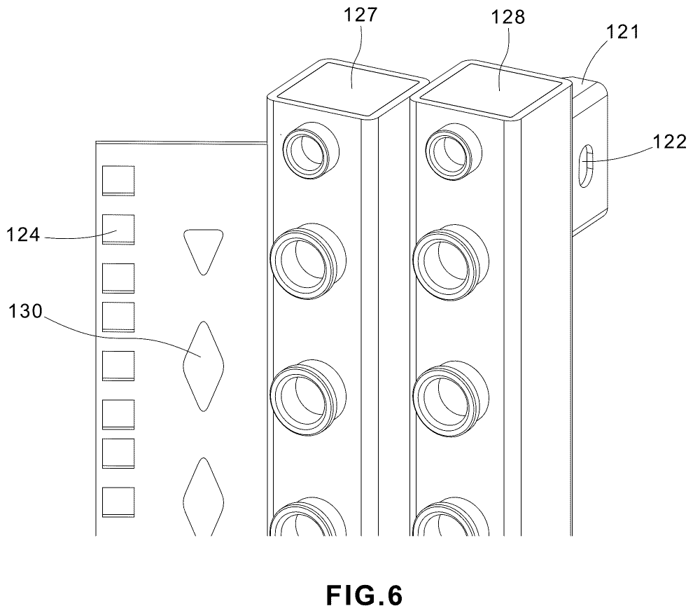

In addition to the standard rectangular tubing manifold which directs the liquid ports directly toward the rear of the cabinet other design options are available. The manifold could route the hoses at a different angle by changing the shape of the rectangular section or the position in which it's affixed in place as illustrated in FIG. 6. FIG. 6 illustrates two manifolds positioned at an angle with respect to each other. The two angled manifolds are positioned on the same side of the cabinet via bracket 121. Alternatively, the manifold could also be made from round tubing and allowed to pivot in position changing the angle the hoses point.

The above describes a cabinet innovatively designed with integral liquid cooling infrastructure. It is contemplated that a rack can also be designed with integral liquid cooling infrastructure. The design allows for the use of a narrower and not as deep cabinet compared to a typical server rack or cabinet using standard manifolds to house the same equipment which uses up less critical data center floor space which is in short supply.

A manifold may also be integrated into a rack or a cabinet by mounting the manifold 150 to an equipment rail 132 secured to the front to back members 60 of the cabinet 50. Mounting the manifold enables the manifold to be serviceable such that the manifold may be removed or maintained without having to remove the equipment rail and the IT equipment attached thereto.

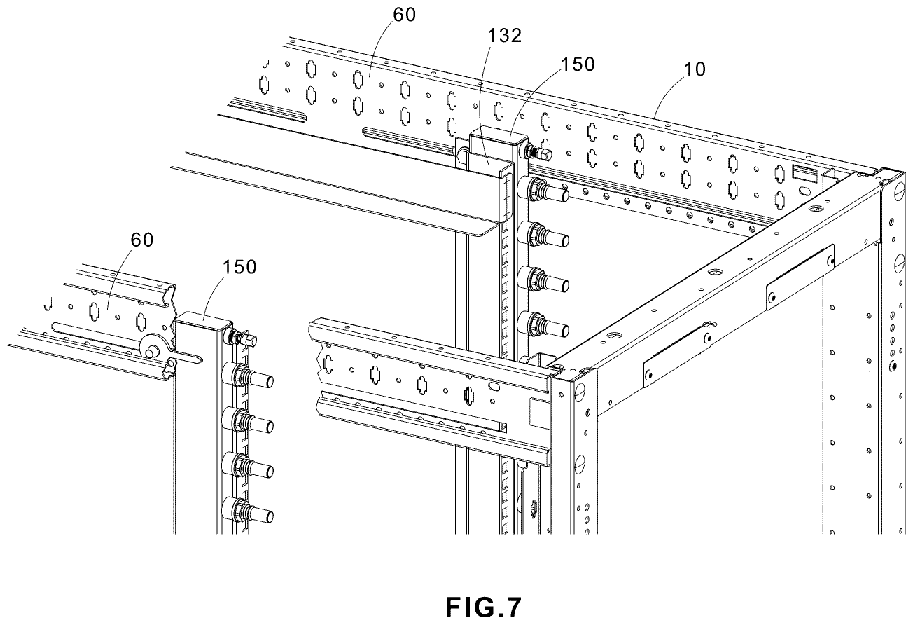

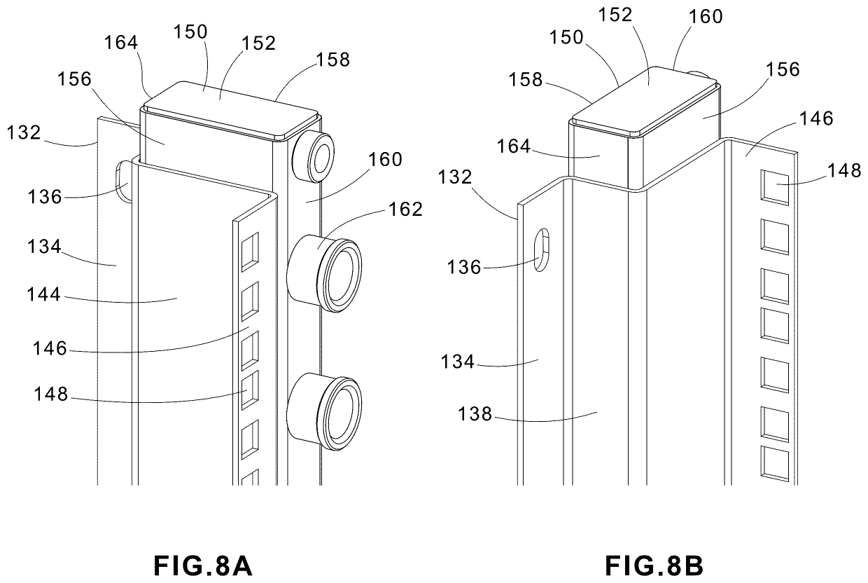

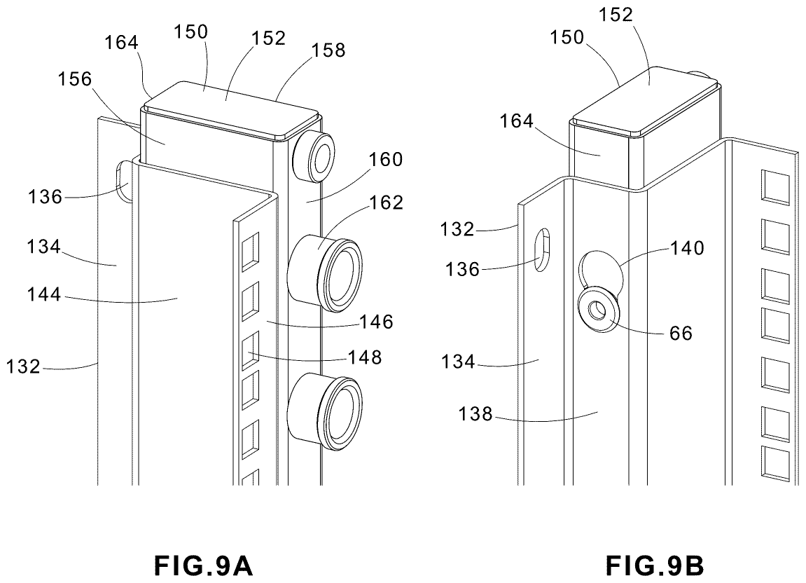

FIGS. 7-12 illustrate and describe mounting the manifold 150 to an equipment rail 132 secured to the front to back members 60 in the cabinet 50. As illustrated in FIGS. 8A-8B and 9A-9B, the equipment rail 132 includes a first member 134 with at least one mounting hole 136, a second member 138, a third member 144, and a fourth member 146 with standard 19-inch rack mounting holes 148 extending the length of the fourth member 46. Additionally, as illustrated in FIGS. 9A-9B, the second member 138 may also include a hole having a larger opening 140 and a small opening 142. The mounting hole 136 in the first member 134 receives a fastener to mount the equipment rail 132 to front to back members 60 in the cabinet 50 as described in commonly owned U.S. Pat. No. 11,678,451.

A rectangular manifold 150 is provided to be positioned against the second member 138 and third member 144 of the equipment rail 132. The manifold 150 includes a top 152, a bottom (not illustrated), a first side 156, a second side 158, a front 160 and a back 164. The front 160 of the manifold 150 includes a plurality of ports 162 for liquid to be distributed to and from the servers. In FIGS. 8A and 8B, the back of the manifold is welded or fixed in a similar fashion to the second member 138 of the equipment rail 132.

In FIGS. 9A and 9B, the back 164 of the manifold 150 includes a mounting button 166 affixed thereto by welding or brazing. The hole in the second member 138 of the equipment rail 132 is designed to receive a mounting button 166 or other fastener extending from the manifold 150. The mounting button 166 is positioned in the larger opening 140 of the hole and then slid to the smaller opening 142 of the hole to mount the manifold 150.

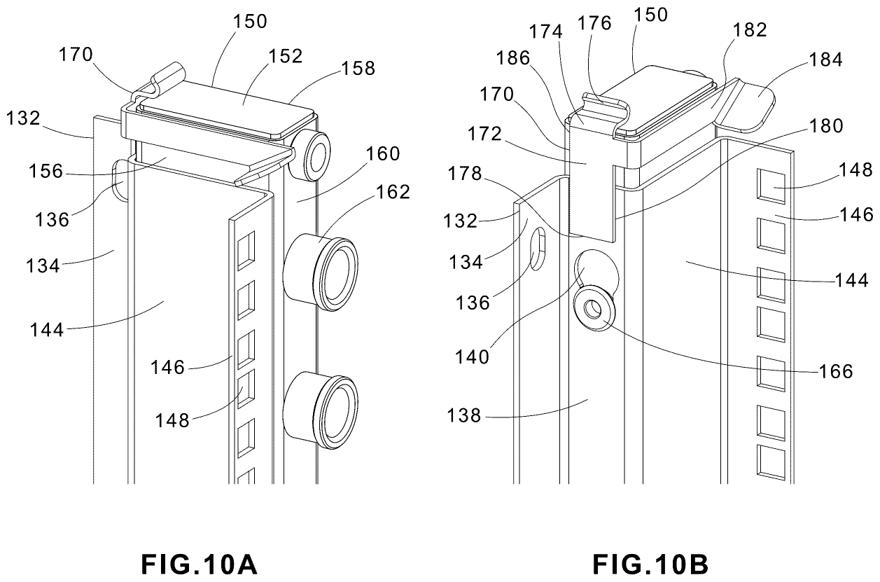

FIGS. 10A-10B illustrates the manifold 150 with a mounting button 166 mounted to the equipment rail 132. The manifold 150 is further secured to the equipment rail 132 by a spring loaded clip 170. As illustrated in FIG. 10B, the spring loaded clip 170 includes a body 172 with a top 174, a bottom 178, a first side 180, a second side 186, a front 192 and a back 194. A portion of the back 194 of the spring loaded clip is permanently attached to the second member 138 of the equipment rail 132 by welding or other means. The top 174 of the spring loaded clip 170 includes a spring hook 176 and the first and second sides 180, 186 each include an arm 182 extending outwardly therefrom (the arm extending from the second side is not illustrated). The arms 182 are parallel to the third member 144 of the equipment rail 132. A distal end of each arm 182 includes a flange 184. As illustrated in FIGS. 10A-10B, when the manifold 150 has been mounted to the equipment rail 132, the spring hook 176 engages the top 152 of the manifold 150 and the arms 182 engage the sides 156, 158 of the manifold 150 to further secure the manifold 150 to the equipment rail 132.

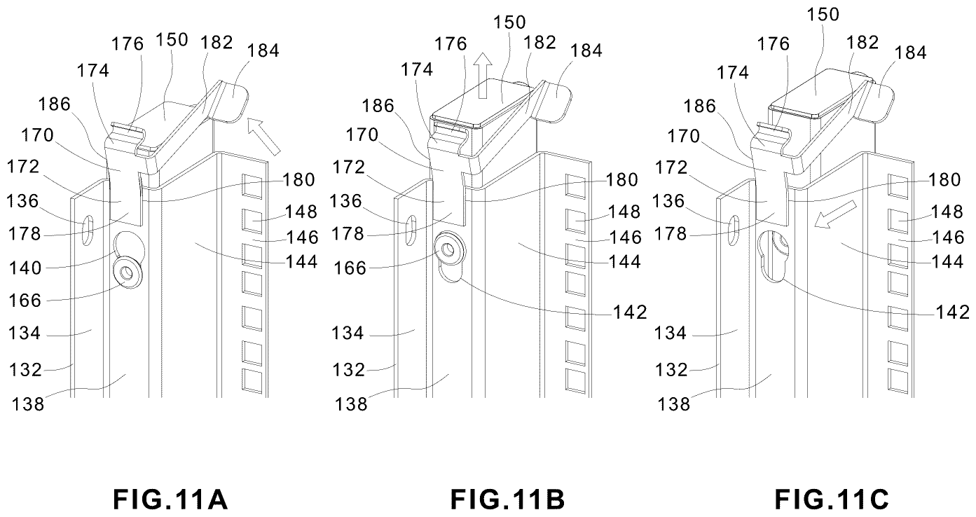

As illustrated in FIGS. 11A, 11B, and 11C, the manifold 50 may be removed from the spring loaded clip 170 and equipment rail 132 by engaging or pushing the spring loaded clip 170 away from the manifold 150 and lifting the manifold 150 to disengage the mounting button 166 from the smaller opening 142 in the equipment rail 132. The spring loaded clip 170 and mounting button 166 provide for an easy tool-less removal of the manifold 150.

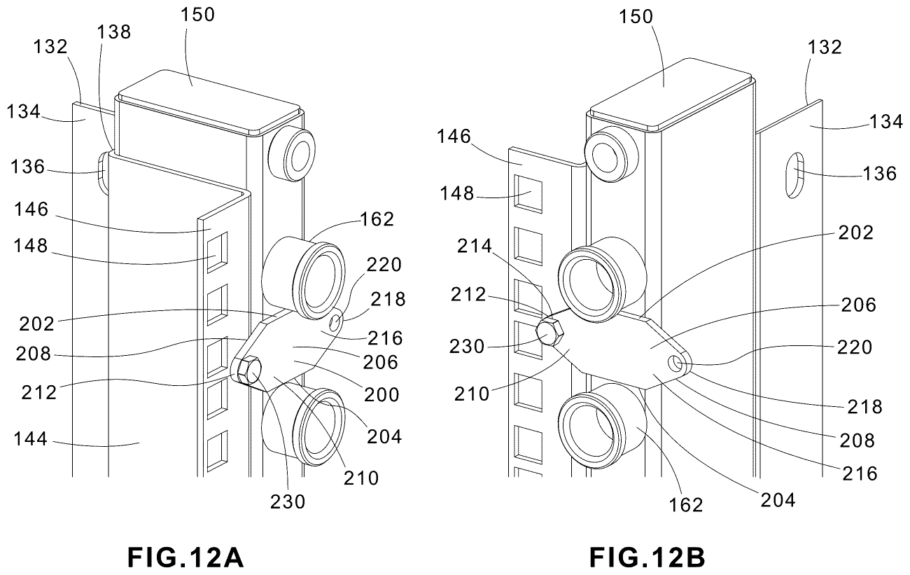

FIGS. 12A-12B illustrates an alternative mount for the manifold 150. The manifold 150 includes at least one mount plate 200 affixed to the manifold 150 by welding or other means. The mount plate 200 is positioned between two ports 162. The mount plate 200 includes a top 202, a bottom 204, a front 206, a back 208, a first side 210, and a second side 216. The first side 210 and the second side 216 include round ends 212, 218. A hole 214, 220 is located adjacent to each side's round end 212, 218, respectively, for receiving a fastener 230 to secure the mount plate 200. As illustrated in FIGS. 12A-12B, the manifold 150 is positioned adjacent to the second member 138 and the third member 144 of the equipment rail 132. The fourth member 146 of the equipment rail 132 includes a number of mounting holes 148 and a number of holes (not illustrated) for receiving the fastener 230 to secure the mount plate 200. The holes 214, 220 at one of the sides of the mount plate 200 aligns with one of the holes in the fourth member 146 of the equipment rail 132. A fastener 230 is installed in the aligned holes to secure the mount plate 200 and manifold 150 to the equipment rail. The mount plate may be formed from other shapes, such as rectangular or elliptical, if desired.

As set forth above, integrating liquid cooling manifolds into a cabinet design leaves more space for other essentials such as power and data equipment. Liquid cooling manifolds may also be integrated into a rack and installed the same as described above with respect to cabinets.

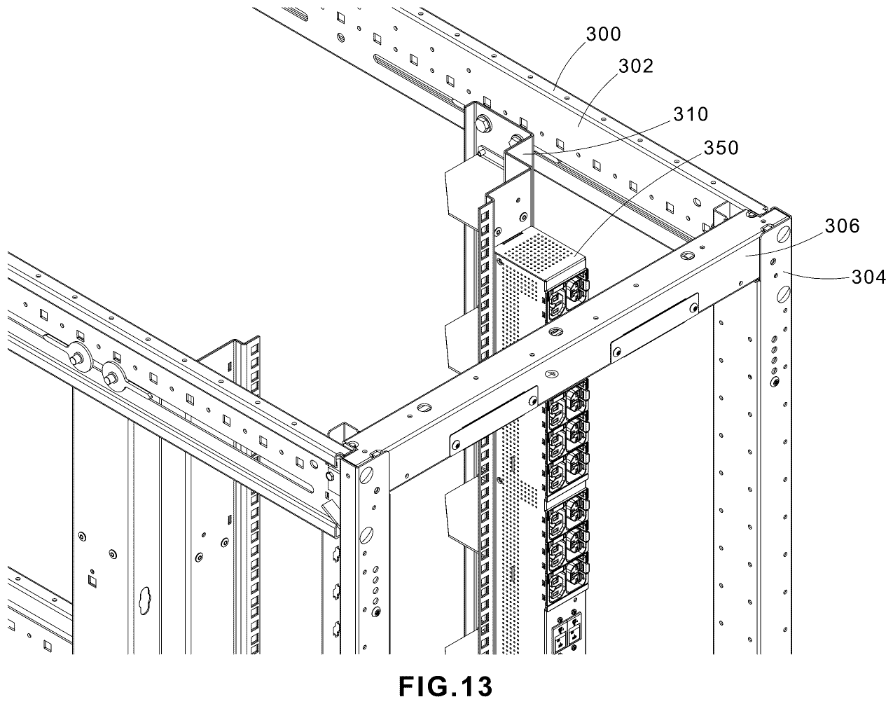

FIGS. 13, 14, 15A and 15B illustrate an in-rack power distribution unit (in-rack PDU) that is secured to an equipment rail in the cabinet to efficiently use the space in the cabinet. The in-rack PDU is integrated into the cabinet infrastructure similar to the manifold as described above. Integrating the in-rack PDU into the cabinet design leaves more space for data cooling, and additional power. Additionally, more than one-in rack PDU could be integrated into the equipment rail.

FIG. 13 illustrates a partial cabinet frame 300 with front to back members 302, front vertical posts 304, and a top side to side member 306. Equipment rails 310 are secured to front to back members 302 in the cabinet as described in commonly owned U.S. Pat. No. 11,678,451. An in-rack PDU 350 is integrated with one of the equipment rails 310. A second in-rack PDU may be integrated into the equipment rails installed on each side of the cabinet, if desired.

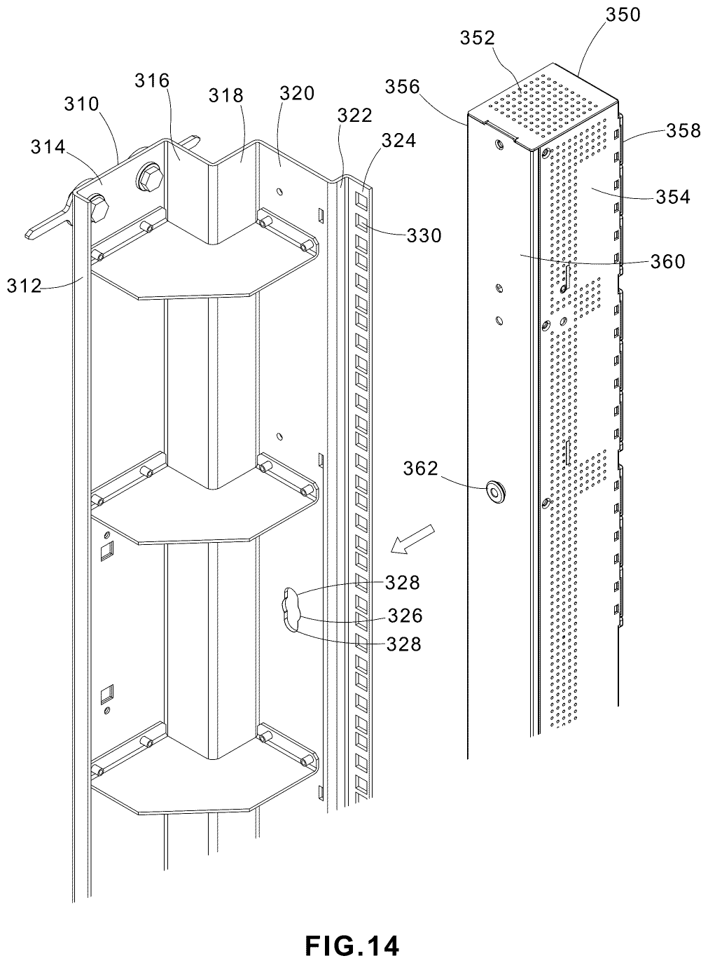

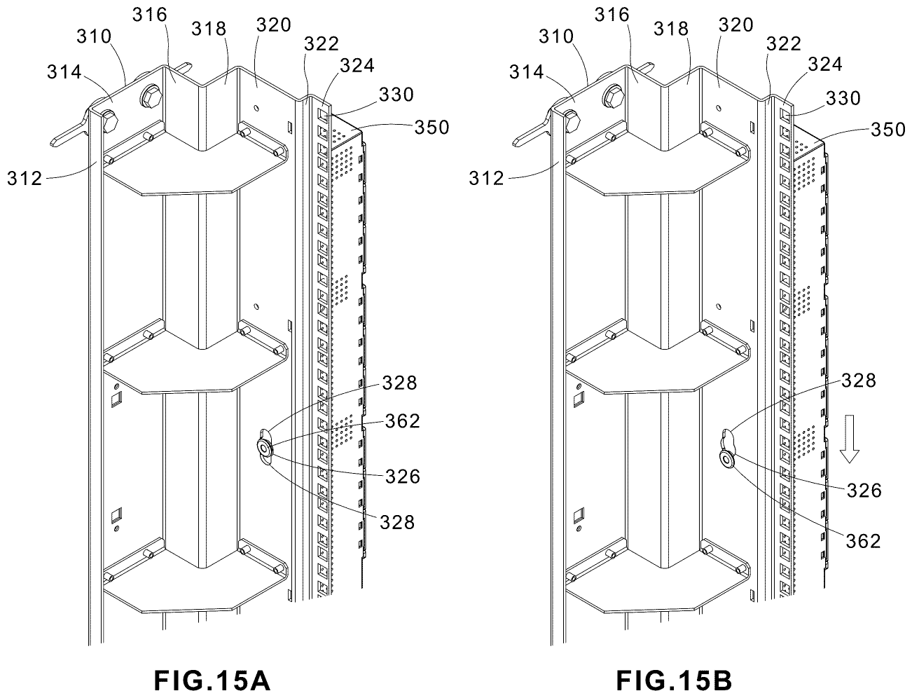

As illustrated in FIG. 14, FIGS. 15A and 15B, the equipment rail 310 includes a first member 312, a second member 314, a third member 316, a fourth member 318, a fifth member 320, a sixth member 322, and a seventh member 324. The fifth member 320 has a hole having a large opening 326 and two smaller openings 328. The seventh member 324 includes a number of mounting holes 330 that extend the length of the equipment rail 310. The in-rack PDU 350 includes a top 352, a bottom (not illustrated), a first side 354, a second side 356, a front 358, and a back 360. The in-rack PDU 350 has a mounting button 362 that is secured to the back 360 by welding, brazing or other similar method. As illustrated in FIGS. 15A and 15B, the mounting button 362 extending from the back 360 of the in-rack PDU 350 is inserted into the large opening 326 in the fifth member 320 of the equipment rail 310. The in-rack PDU 350 is then slid downwards so the mounting button 362 is positioned in one of the smaller openings 328 in the fifth member 320 of the equipment rail 310 to secure the in-rack PDU 350 thereto.

Furthermore, while the particular preferred embodiments of the present invention have been shown and described, it will be obvious to those skilled in the art that changes and modifications may be made without departing from the teaching of the invention. The matter set forth in the foregoing description and accompanying drawings is offered by way of illustration only and not as limitation.

1. A data center cabinet comprising:
a plurality of front to back members;
a first manifold secured to at least one of the plurality of front to back members on a first side of the cabinet and a second manifold secured to at least one of the plurality of front to back members on a second side of the cabinet;
whereby the first manifold and the second manifold provide liquid to be distributed to and from equipment installed in the cabinet.

2. The data center cabinet of claim 1, wherein the first manifold has a first bracket extending from a side of the first manifold, the first bracket has a mounting hole for receiving a fastener to mount the first manifold to the front to back member; and
wherein the second manifold has a first bracket extending from a side of the second manifold, the first bracket has a mounting hole for receiving a fastener to mount the second manifold to the front to back member.

3. The data center cabinet of claim 2, wherein the first manifold has a second bracket extending from an opposite side of the first manifold, the second bracket has a plurality of mounting holes extending a length of the second bracket; and wherein the second manifold has a second bracket extending from an opposite side of the second manifold, the second bracket has a plurality of mounting holes extending a length of the second bracket.

4. The data center cabinet of claim 1, wherein the first manifold includes a hot manifold and a cold manifold positioned adjacent to the hot manifold.

5. The data center cabinet of claim 4, wherein the hot manifold and the cold manifold are positioned at a different angle with respect to the plurality of front to back members.

6. The data center cabinet of claim 1, wherein the data center cabinet further comprising a plurality of equipment rails; wherein at least one of the plurality of equipment rails is mounted to one of the plurality of front to back members on the first side of the cabinet and at least one of the plurality of equipment rails is mounted to one of the plurality of equipment rails on the second side of the cabinet; and
wherein the first manifold is mounted to the at least one of the plurality equipment rails mounted to the front to back member on the first side of the cabinet and the second manifold is mounted to the at least one of the plurality of equipment rails mounted to the front to back member on the second side of the cabinet.

7. The data center cabinet of claim 6, wherein the plurality of equipment rails include a first member with at least one mounting hole, a second member, a third member, and a fourth member with mounting holes extending the length of the fourth member;
wherein the first manifold and the second manifold both have a top, a bottom, a first side, a second side, a front, and a back; and
wherein the front of first and second manifold includes a plurality of ports.

8. The data center cabinet of claim 7, wherein the back of the first manifold is welded to the second member of one of the plurality of equipment rails and the back of the second manifold is welded to second member of one of the plurality of equipment rails.

9. The data center cabinet of claim 7, the second member of the plurality of equipment rails includes a hole with a large opening and a small opening, and the back of the first manifold and the back of the second manifold each include a mounting button;
whereby the mounting button on the back of the first manifold and the mounting button on the back of the second manifold are positioned in the large openings of the holes in the second member of one of the plurality of equipment rails and slid to the smaller openings of the holes to mount the first manifold and the second manifold to one of the plurality of equipment rails.

10. The data center cabinet of claim 9, further comprising at least one spring loaded clip for further securing one of the first and second manifolds to one of the plurality of equipment rails.

11. The data center cabinet of claim 10, wherein the at least one spring loaded clip includes a body with a top having a spring hook, a bottom, a first side with an outwardly extending first arm, a second side with an outwardly extending second arm, a front, and a back; and wherein a portion of the back is attached to the second member of one of the plurality of equipment rails.

12. The data center cabinet of claim 11, wherein the spring hook engages the top of one of the first and second manifolds and the first and second arms engage the sides of one of the first and second manifolds to secure the one of the first and second manifolds to the one of the plurality of equipment rails.

13. The data center cabinet of claim 9, further comprising at least one mounting plate secured to one of the first and second manifolds.

14. The data center cabinet of claim 13, wherein the at least one mounting plate includes a top, a bottom, a first side with a round end, a second side with a round end, a front and a back; wherein the round end of the first side includes a mounting hole for receiving a fastener to secure the mounting plate and the round end of the second side includes a mounting hole for receiving a fastener to secure the mounting plate.

15. A data center cabinet comprising:
a plurality of front to back members;
a plurality of equipment rails; wherein at least one of the plurality of equipment rails is mounted to one of the plurality of front to back members on a first side of the cabinet and at least one of the plurality of equipment rails is mounted to one of the plurality of front to back members on a second side of the cabinet, wherein at least one of the plurality of equipment rails includes a hole with a large opening and a small opening; and
at least one in-rack power distribution unit, a back of the at least one in-rack power distribution units includes a mounting button, wherein the mounting button on the back of the in-rack power distribution is positioned in one of the large openings of the holes in one of the plurality of equipment rails and slid to the smaller opening of the hole to mount the at least one in-rack power distribution unit to the at least one of the plurality of equipment rails.
